(19) United States
(12) Patent Application Publication
(10) Pub. No.: US 2005/0110109 A1
(43) Pub. Date: May 26, 2005

(54) Semiconductor device manufacturing method and semiconductor device manufactured by such manufacturing method

(75) Inventors: Hidetoshi Washio, Kashihara-shi (JP); Tatsuya Takamoto, Ikoma-gun (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 10/988,698

(22) Filed: Nov. 16, 2004

(30) Foreign Application Priority Data
Nov. 20, 2003 (JP) 2003-390944

(51) Int. Cl. H01L 23/58

(52) U.S. Cl. 257/496

(57) ABSTRACT

After patterning employing photolithographic and/or other such technique(s) following resist film formation, small amount(s) of surface(s) at exposed portion(s) of crystal(s) 1 is or are at least partially removed therefrom by etching as a result of immersion in etchant(s). Metal film(s) is/are thereafter formed over surface(s) of exposed crystal(s) 1 and over photoresist remaining following etching operation(s), and photoresist remaining following etching operation(s) is then removed so as to cause metal film(s) to remain only at surface(s) of crystal(s) 1 exposed at patterning operation(s).

### BACKGROUND OF INVENTION

This application claims priority under 35 USC 119(a) to Patent Application No. 2003-390944 filed in Japan on 20 Nov. 2003, the content of which is incorporated herein by reference in its entirety.

The present invention relates to a semiconductor device manufacturing method and to a semiconductor device manufactured by such manufacturing method. In particular, the present invention pertains to a strategy for, when forming metal wiring and/or the like in finely patterned fashion over epitaxial layer(s) and/or crystal(s), ensuring that there will be good adhesion at such metal material(s).

There are a variety of conventionally known patterned metal wiring formation methods used in forming electrodes for semiconductor integrated circuits, solar cells, and so forth. Chiefly used among these is the liftoff technique.

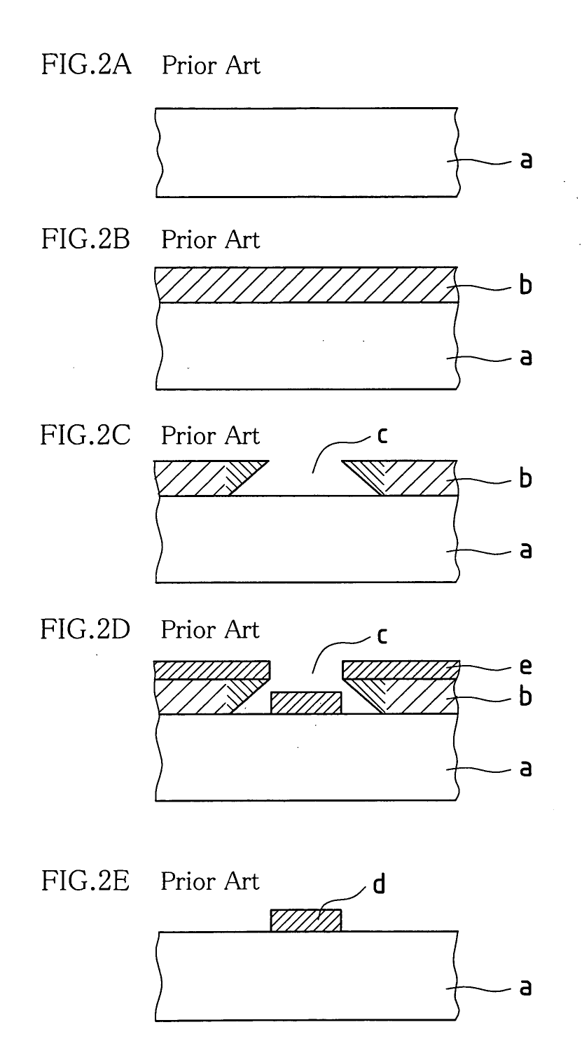

A through E at FIG. 2 are cross-sectional views for explaining a conventional liftoff technique; in accordance with this procedure, Ti and/or AuGe might, for example, be used as first metal wiring layer over semiconductor crystal and/or over an epitaxial layer grown on the crystal surface.

Reference numeral 21 in the drawings is Ge, GaAs, GaP, or Si semiconductor crystal, the top surface thereof being coated with on the order of 100 to 200 nm of resist 22 (see FIG. 2B), and normal photolithographic techniques being used to pattern the resist following resist film formation (see FIG. 2C). Reference numeral 23 in the drawings is a window portion 23 that has been created as a result of photolithography operations; patterned metal wiring 24 will be formed therewithin. That is, after the foregoing resist pattern has been formed, electron-beam vapor deposition might, for example, be used to vapor-deposit Ti and/or AuGe—indicated by reference numeral 25 in the drawings—as first metal layer over the entire surface of semiconductor crystal and/or over an epitaxial layer grown on the crystal surface (see FIG. 2D). Furthermore, because window portion 23 of resist 22 as created for liftoff operations is normally formed such that the sidewall thereof is undercut as shown at FIG. 2D, immersion in solution causes separation of resist 22 such that, as shown at FIG. 2E, only the desired metal pattern 24 remains over the crystal and/or over the epitaxial layer.

However, as disclosed at Japanese Patent No. 3407146 (hereinafter “Patent Reference No. 1”), when such operations are carried out it has been found through Auger electron spectroscopy that an ultrathin organic layer remains even where done following develop operations for normal resist pattern formation.

It is the opinion of the inventor that, when the fractional amount of the ultrathin organic layer above the crystal and/or above an epitaxial layer grown on the crystal surface is large, it is possible, if adhesion at patterned metal 24 were to become extremely poor, that during separation of resist 22 by liftoff, the patterned metal 24 intended to be metal wiring might also separate from the crystal and/or the epitaxial layer, preventing formation of the desired metal pattern.

Furthermore, in the case of normal metal-semiconductor contacts involving alloying and/or heat treatment, where heat treatment operations are carried out, phenomena such as generation of gas by an ultrathin organic layer between metal and semiconductor crystal and/or an epitaxial layer grown over crystal could adversely affect adhesion. Furthermore, with regard to Patent Reference No. 1, as it is the case that the foregoing ultrathin organic layer is not eliminated even where the workpiece has been subjected to heat treatment in the form of so-called sintering operations, the ultrathin organic layer that remains tends to increase contact resistance.

Presence of an ultrathin organic film accompanying liftoff operations at the metal-semiconductor contact interface thus causes increase in contact resistance at metal-semiconductor contacts, causing adhesion to deteriorate and moreover interfering with ability to achieve the excellent characteristics that the device should possess.

Japanese Patent Application Publication Kokai No. H5-343346 (1993) (hereinafter “Patent Reference No. 2”) therefore proposes a method in which window portion 23 produced by photolithography operations is irradiated with ozone, chemically removing the ultrathin organic layer and utilizing the oxidizing power of ozone to oxidize the semiconductor surface in the region that will undergo develop, and the oxide film formed by ozone is thereafter etched away together with the ultrathin organic layer. Also proposed at Patent Reference No. 1 is a method in which satisfactory liftoff characteristics are obtained without causing deterioration of the resist pattern, low-temperature oxidation being carried out on the resist pattern prior to formation of the metal film in order to remove any organic thin film that might remain in ultrathin fashion over the semiconductor crystal after the resist has been subjected to develop processing.

### SUMMARY OF INVENTION

However, in the case of the conventional art in which oxidizing operations and/or heat treatment operations are carried out following formation of the metal pattern, this could lead to increase in the time required for processing due to such operations, and such processing could lead to new difficulties (generation of gas accompanying heat treatment, etc.).

The present invention was conceived in light of such issues, it being an object thereof to provide a semiconductor device manufacturing method and a semiconductor device manufactured by such manufacturing method making it possible to reproducibly form low-resistance metal-semiconductor contacts having good adhesion through use of liftoff technique(s) suitable for formation of finely detailed pattern(s) without any need to carry out oxidizing operations and/or heat treatment operations.

Solution means employed by one or more embodiments of the present invention for achieving the foregoing and/or other object(s) is such that, after patterning employing photolithographic and/or other such technique(s) following resist film formation, small amount(s) of surface(s) at exposed portion(s) of epitaxial layer(s) and/or crystal(s) is or are at least partially removed therefrom through use of etchant(s). That is, prior to formation of metal film(s) for formation of electrode(s) and/or the like, etching to remove residual organic thin film(s) together with surface(s) of epitaxial layer(s) and/or crystal(s) makes it possible to obtain satisfactory adhesion of metal film(s) formed thereafter for epitaxial layer(s) and/or crystal(s).

More specifically, a semiconductor device manufacturing method in accordance with one or more embodiments of the present invention may comprise carrying out, in order, one or more resist forming operations in which liftoff photoresist is formed over one or more epitaxial layers and/or one or more crystals; one or more patterning operations in which at least a portion of the photoresist is patterned, exposing one or more portions of at least one of the epitaxial layer or layers and/or at least one of the crystal or crystals; one or more etching operations in which one or more small amounts of one or more surfaces at at least one of the exposed portion or portions of at least one of the epitaxial layer or layers and/or at least one of the crystal or crystals is or are at least partially removed therefrom by etching as a result of immersion in one or more etchants; one or more metal film forming operations in which one or more metal films is or are formed over at least one of the surface or surfaces of at least one of the epitaxial layer or layers and/or at least one of the crystal or crystals exposed at at least one of the patterning operation or operations and over at least a portion of the photoresist remaining following at least one of the etching operation or operations; and one or more resist removal operations in which at least a portion of the photoresist remaining following at least one of the etching operation or operations is removed so as to cause at least one of the metal film or films to remain only at at least one of the surface or surfaces of at least one of the epitaxial layer or layers and/or at least one of the crystal or crystals exposed at at least one of the patterning operation or operations.

In accordance with the foregoing constitution, prior to formation of metal film(s), small amount(s) is/are first etched from resist pattern(s) in which window(s) has or have been created over epitaxial layer(s) and/or crystal(s) by means of patterning operation(s) (photolithography operations). In accordance herewith, following resist develop, organic thin film(s) remaining in ultrathin fashion over semiconductor crystal(s) and/or epitaxial layer(s) grown over crystal(s) is/are etched away therefrom together with crystal and/or epitaxial layer surface(s). This makes it possible for metal film(s) to be formed on crystal and/or epitaxial layer surface(s) that has or have been made extremely clean, makes it possible to ensure good adhesion at such metal film(s), and makes it possible to achieve low-resistance metal-semiconductor contacts having low contact resistance without having to carry out heat treatment operation(s). Furthermore, because it is possible to employ very weakly acidic and/or alkaline solution(s) for etching, and because it is possible for etching to be completed in short period(s) of time, it is possible to obtain satisfactory liftoff characteristics without causing deterioration of resist pattern(s).

Furthermore, at least one of the epitaxial layer or layers and/or at least one of the crystal or crystals may be one or more GaAs-type compound and/or may be one or more GaP-type compound. Moreover, at least one of the crystal or crystals may be Ge.

Alternatively or in addition thereto, at least one solution used as at least one of the etchant or etchants may be at least one alkaline aqueous solution containing ammonia, and/or may be at least one acidic aqueous solution containing sulfuric acid and/or hydrochloric acid.

As actual mode(s) for using such etchant(s), ammonia-type and/or sulfuric-acid-type etchant(s) might be used for etching where surface(s) on which vapor deposition is to be carried out is/are GaAs-type epitaxial layer(s), GaAs-type crystal(s), and/or Ge crystal(s). Furthermore, hydrochloric-acid-type etchant(s) might be used for etching where surface(s) on which vapor deposition is to be carried out is/are GaP-type epitaxial layer(s) and/or GaP-type crystal(s).

Semiconductor device(s) in accordance with embodiment(s) of the present invention may be manufactured by semiconductor device manufacturing method(s) associated with any one of the foregoing several solution means, metal film(s) being formed over only portion(s) of epitaxial layer(s) and/or crystal(s).

### BRIEF DESCRIPTION OF DRAWINGS

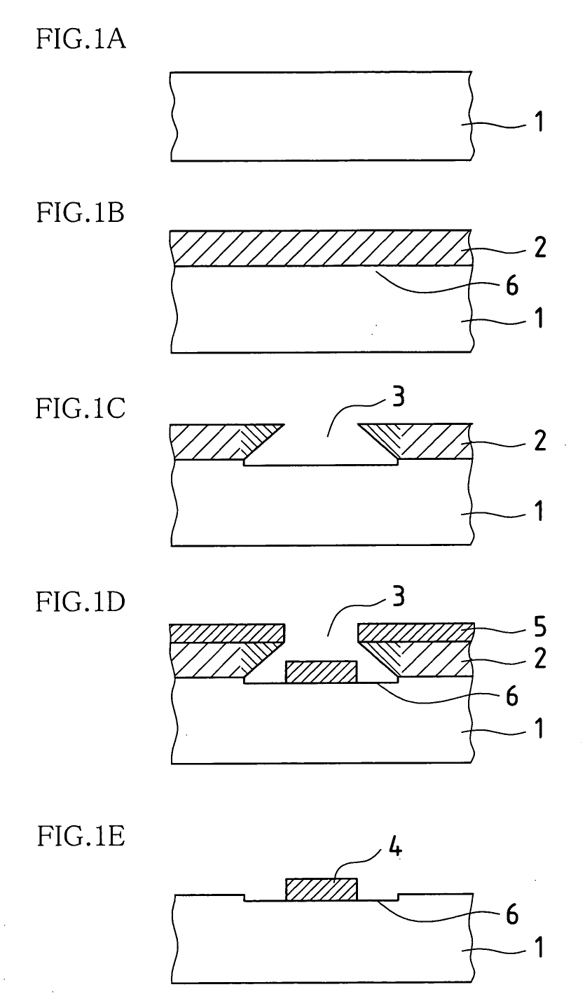

A through E at FIG. 1 are cross-sectional views for explaining liftoff techniques associated with embodiments.

A through E at FIG. 2 are cross-sectional views for explaining a conventional liftoff technique.

### DESCRIPTION OF PREFERRED EMBODIMENTS

Below, embodiments of the present invention are described with reference to the drawings. FIG. 1 contains cross-sectional views showing liftoff operations in chronological fashion, these constituting a method for manufacturing a semiconductor device associated with the present embodiment.

Note, in the drawing, that as formation of resist pattern(s) indicated by reference numeral 2 over crystal(s) indicated by reference numeral 1 (resist forming operations and patterning operations) is similar to that in the conventional art, description is omitted here.

Following formation of resist pattern(s), where surface(s) on which vapor deposition is to be carried out is/are InGaAs epitaxial layer(s), GaAs epitaxial layer(s), InGaAs crystal(s), GaAs crystal(s), Ge crystal(s), and/or other material(s) etched using ammonia-type and/or sulfuric-acid-type etchant(s), etchant(s) employed should have components in ratio(s) on the order of NH₄OH:H₂O₂: H₂O=1:1:100 and/or H₂SO₄: H₂O₂: H₂O=1:1:100.

On the other hand, where surface(s) on which vapor deposition is to be carried out is/are InGaP epitaxial layer(s), GaP epitaxial layer(s), InGaP crystal(s), GaP crystal(s), and/or other material(s) etched using hydrochloric-acid-type etchant(s), etchant(s) employed should have components in ratio(s) on the order of HCl:H₂O₂: H₂O=1:1:100.

Such etchant(s) is/are used for on the order of 10 seconds to etch surface(s) on which vapor deposition is to be carried out (etching operation). This operation makes it possible to etch and remove, together with etching of epitaxial layer and/or crystal surface(s), ultrathin organic layer(s) not completely removed despite develop processing taking place during formation of resist pattern 2 and operation(s) occurring thereafter. Note that such etching and/or removal is directed at window portion(s) 3 (i.e., what is referred to in the context of the present invention as exposed portion(s)) of resist pattern 2.

Because the fact that such etching operation(s) is/are carried out makes it unnecessary to perform carbonization and/or oxidation involving ozone, ultraviolet irradiation, and/or the like, and because etchant concentration(s) may be extremely low and processing need last only a short period of time, it is possible to avoid resist pattern deformation and it is possible to prevent adverse effect on liftoff. Moreover, when using etchant to etch crystal(s) and/or epitaxial layer(s) grown over crystal(s), while the reduction in thickness due to etching will depend upon the combination of etchant(s) and etched crystal(s) and/or epitaxial layer(s) grown over crystal(s), on the order of roughly 5 nm of crystal and/or epitaxial layer grown over crystal can be expected to be etched away together with the ultrathin organic layer (see region indicated by reference numeral 6 at FIG. 1C). Because surface(s) on which vapor deposition is to be carried out will be extremely clean immediately following such etching, it is desirable that this etching operation be performed immediately prior to the vapor deposition operation that is carried out subsequent thereto.

Following such etching operation, electron-beam vapor deposition is used to form, for example, approximately 200 nm of Ti and/or AuGe, serving as first metal wiring layer 5, over the entire surface of the semiconductor crystal(s) and/or the epitaxial layer(s) grown on crystal(s) (metal film forming operation; see FIG. 1D).

The workpiece is thereafter immersed in acetone or other such solvent to cause liftoff to take place, leaving the desired metal pattern 4 (resist removal operation; see FIG. 1E). More specifically, because window portion(s) 3 as formed by patterning operation(s) is/are formed such that sidewall(s) thereof is/are undercut, immersion in the foregoing etchant(s) causes separation of resist 2 such that, as shown at FIG. 1E, only the desired metal pattern 4 remains over crystal(s) 1.

As a result of the foregoing, it is possible to achieve liftoff of a quality that is in no way inferior to the conventional method. Furthermore, the metal wiring obtained by this method has good adhesion and can be formed with good reproduceability, and the contact resistance thereat is moreover low. Where heat treatment operation(s) in accordance with the conventional art is/are thereafter carried out in the event that there is a desire to further improve adhesion, it has been observed that, because of the absence of the ultrathin organic layer on top of crystal(s) and/or epitaxial layer(s) grown over crystal(s), such heat treatment operation(s) do not have the unintended effect of diminishing adhesion due to occurrence of phenomena such as generation of gas.

The present invention is not limited to patterns employing resist, and can also be applied to polyimide and/or other organic films. Furthermore, the present invention may, needless to say, be applied not only to semiconductors but also in any other context where fine pattern formation is required. Because formation of proper metal-semiconductor contact(s) is permitted thereby, operation(s) in accordance with the present invention is/are not limited to formation of contact layer(s) having low-resistance metal-semiconductor contact(s) but may also be applied, for example, to formation of satisfactory Schottky barrier(s).

Moreover, the present invention may be embodied in a wide variety of forms other than those presented herein without departing from the spirit or essential characteristics thereof. The foregoing embodiments, therefore, are in all respects merely illustrative and are not to be construed in limiting fashion. The scope of the present invention being as indicated by the claims, it is not to be constrained in any way whatsoever by the body of the specification. All modifications and changes within the range of equivalents of the claims are, moreover, within the scope of the present invention.

1. A semiconductor device manufacturing method comprising carrying out, in order:
one or more resist forming operations in which liftoff photoresist is formed over one or more epitaxial layers and/or one or more crystals;
one or more patterning operations in which at least a portion of the photoresist is patterned, exposing one or more portions of at least one of the epitaxial layer or layers and/or at least one of the crystal or crystals;
one or more etching operations in which one or more small amounts of one or more surfaces at at least one of the exposed portion or portions of at least one of the epitaxial layer or layers and/or at least one of the crystal or crystals is or are at least partially removed therefrom by etching as a result of immersion in one or more etchants;
one or more metal film forming operations in which one or more metal films is or are formed over at least one of the surface or surfaces of at least one of the epitaxial layer or layers and/or at least one of the crystal or crystals exposed at at least one of the patterning operation or operations and over at least a portion of the photoresist remaining following at least one of the etching operation or operations; and
one or more resist removal operations in which at least a portion of the photoresist remaining following at least one of the etching operation or operations is removed so as to cause at least one of the metal film or films to remain only at at least one of the surface or surfaces of at least one of the epitaxial layer or layers and/or at least one of the crystal or crystals exposed at at least one of the patterning operation or operations.

2. A method of manufacturing a semiconductor device according to claim 1 wherein
at least one of the epitaxial layer or layers and/or at least one of the crystal or crystals is or are one or more GaAs-type compound.

3. A method of manufacturing a semiconductor device according to claim 1 wherein at least one of the epitaxial layer or layers and/or at least one of the crystal or crystals is or are one or more GaP-type compound.

4. A method of manufacturing a semiconductor device according to claim 1 wherein at least one of the crystal or crystals is Ge.

5. A method of manufacturing a semiconductor device according to claim 1 wherein
at least one alkaline aqueous solution containing ammonia is used as at least one of the etchant or etchants.

6. A method of manufacturing a semiconductor device according to claim 1 wherein
at least one acidic aqueous solution containing sulfuric acid is used as at least one of the etchant or etchants.

7. A method of manufacturing a semiconductor device according to claim 1 wherein
at least one acidic aqueous solution containing hydrochloric acid is used as at least one of the etchant or etchants.

8. A semiconductor device manufactured by the manufacturing method according to claim 1 wherein
at least one of the metal film or films is formed over only a portion of at least one of the epitaxial layer or layers and/or at least one of the crystal or crystals.

9. A method of manufacturing a semiconductor device according to claim 2 wherein
at least one alkaline aqueous solution containing ammonia is used as at least one of the etchant or etchants.

10. A method of manufacturing a semiconductor device according to claim 3 wherein
at least one alkaline aqueous solution containing ammonia is used as at least one of the etchant or etchants.

11. A method of manufacturing a semiconductor device according to claim 4 wherein
at least one alkaline aqueous solution containing ammonia is used as at least one of the etchant or etchants.

12. A method of manufacturing a semiconductor device according to claim 2 wherein
at least one acidic aqueous solution containing sulfuric acid is used as at least one of the etchant or etchants.

13. A method of manufacturing a semiconductor device according to claim 3 wherein
at least one acidic aqueous solution containing sulfuric acid is used as at least one of the etchant or etchants.

14. A method of manufacturing a semiconductor device according to claim 4 wherein
at least one acidic aqueous solution containing sulfuric acid is used as at least one of the etchant or etchants.

15. A method of manufacturing a semiconductor device according to claim 2 wherein
at least one acidic aqueous solution containing hydrochloric acid is used as at least one of the etchant or etchants.

16. A method of manufacturing a semiconductor device according to claim 3 wherein
at least one acidic aqueous solution containing hydrochloric acid is used as at least one of the etchant or etchants.

17. A method of manufacturing a semiconductor device according to claim 4 wherein
at least one acidic aqueous solution containing hydrochloric acid is used as at least one of the etchant or etchants.

18. A semiconductor device manufactured by the manufacturing method according to claim 2 wherein
at least one of the metal film or films is formed over only a portion of at least one of the epitaxial layer or layers and/or at least one of the crystal or crystals.

19. A semiconductor device manufactured by the manufacturing method according to claim 3 wherein
at least one of the metal film or films is formed over only a portion of at least one of the epitaxial layer or layers and/or at least one of the crystal or crystals.

20. A semiconductor device manufactured by the manufacturing method according to claim 4 wherein
at least one of the metal film or films is formed over only a portion of at least one of the epitaxial layer or layers and/or at least one of the crystal or crystals.
